(19) United States
(12) Patent Application Publication
(10) Pub. No.: US 2024/0332124 A1
(43) Pub. Date: Oct. 3, 2024

(54) POROUS STRUCTURE WITH MICROCHANNELS

(71) Applicants: Toyota Motor Engineering & Manufacturing North America, Inc., Plano, TX (US); The Board of Trustees of the University of Illinois, Urbana, IL (US)

(72) Inventors: Sujan Dewanjee, Urbana, IL (US); Gaurav Singhal, Mumbai (IN); Nenad Milijkovic, Urbana, IL (US); Paul V. Braun, Champaign, IL (US); Danny Lohan, Northville, MI (US); Shailesh Joshi, Ann Arbor, MI (US)

(73) Assignees: Toyota Motor Engineering & Manufacturing North America, Inc., Plano, TX (US); The Board of Trustees of the University of Illinois, Urbana, IL (US)

(21) Appl. No.: 18/129,409

(22) Filed: Mar. 31, 2023

(51) Int. Cl. H01L 23/373; H01L 21/311; H01L 21/3205

(52) U.S. Cl. CPC H01L 23/3736; H01L 21/31138; H01L 21/32051

(57) ABSTRACT

Porous structures and processes for generating porous structures are disclosed. In one embodiment, a porous structure includes a target surface, a photoresist material deposited onto the target surface, and a metal electrodeposited onto the target surface and the photoresist material. An electrodeposition of metal generates a metal porous structure and the photoresist material is removed through reactive ion etching, generating at least one microchannel through the metal porous structure.

### TECHNICAL FIELD

The present specification generally relates to cooling structures for electronics modules and, more specifically, to microchannel heat sinks through a porous structure for cooling heat-generating devices in electronics modules.

### BACKGROUND

Cooling fluid may be used to receive heat generated by the heat-generating device by thermal transfer, and remove such heat from the heat-generating device. For example, cooling fluid may be directed toward a semiconductor-cooling chip to remove heat from the heat-generating device. For small electronic devices such as integrated circuits, a microchannel heat sink may be used to accommodate the small size of these devices.

Power electronics devices are designed to operate at increased power levels and generate increased corresponding heat flux due to the demands of newly-developed electrical systems. Conventional heat sinks may be unable to adequately remove sufficient heat to effectively lower the operating temperature of the electronic assemblies to acceptable temperature levels. Further, conventional heat sinks and cooling structures may require additional bonding layers and thermal matching materials (e.g., bond layers, substrates, thermal interface materials). These additional layers and other factors add packaging size and substantial thermal resistance to the overall electronics modules and make their thermal management challenging.

Due to the trending demand of high efficiency, integrated-functionality and compact form factor, the power density of power electronics devices has been inevitably increasing. As a result, the thermal management of such power-dense electronics modules requires higher heat dissipation capability with balanced pumping power requirement. Accordingly, innovative cooling solutions are desirable to address the thermal management requirements of these power-dense electronics modules.

### SUMMARY

The present specification relates to microporous structures having microchannels that provide nucleation sites for two-phase cooling of heat-generating devices in electronics modules. In one embodiment, a porous structure includes a target surface and a photoresist material deposited onto the target surface. The porous structure includes a metal electrodeposited onto the target surface and the photoresist material, wherein an electrodeposition of metal generates a metal porous structure and the photoresist material is removed through reactive ion etching, generating at least one microchannel through the metal porous structure.

In another embodiment, a process for generating a porous structure is disclosed. The process may include depositing a photoresist material onto a target surface and electrodepositing a metal onto the target surface and the photoresist material. The electrodepositing generates a metal porous structure. The process for generating a metal porous structure further includes removing the photoresist material through reactive ion etching. Removing the photoresist material through the reactive ion etching generates at least one microchannel through the metal porous structure.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically illustrates a flowchart of a process for generating a porous structure, according to one or more embodiments shown and described herein;

FIG. 2A schematically illustrates a top-view of a photoresist material on a target surface, according to one or more embodiments shown and described herein;

FIG. 2B schematically illustrates a side-view of the photoresist material and a metal porous structure, according to one or more embodiments shown and described herein;

FIG. 3 schematically illustrates a process of electroplating a metal onto the target surface having the photoresist material deposited thereto, according to one or more embodiments shown and described herein;

FIG. 4A schematically illustrates a top-view of a high porosity metal porous structure, according to one or more embodiments shown and described herein;

FIG. 4B schematically illustrates a top-view of a low porosity metal porous structure, according to one or more embodiments shown and described herein;

FIG. 5A schematically illustrates a closed microchannel, according to one or more embodiments shown and described herein;

FIG. 5B schematically illustrates an open microchannel, according to one or more embodiments shown and described herein;

FIG. 6A schematically illustrates a closed enclosed microchannel, according to one or more embodiments shown and described herein; and

FIG. 6B schematically illustrates an open enclosed microchannel, according to one or more embodiments shown and described herein.

### DETAILED DESCRIPTION

Various embodiments described herein are directed to a porous structure with microchannels to provide enhanced cooling of electronic devices. The porous structure includes a target surface, a photoresist material deposited onto the target surface, and metal electrodeposited onto the target surface and the photoresist material. Electrodeposition of the metal generates a metal porous structure on the target surface. The photoresist material is removed through reactive ion etching (RIE), which generates at least one microchannel though the metal porous structure.

Porous structure heat sinks may be used to receive heat generated by a heat-generating device by thermal transfer, and remove such heat from a heat-generating device when cooling fluid is ran through the porous structure. However, it may be difficult to pass the cooling fluid through the porous structure without a high pressure drop due to the pores being too small. Thus, there exists a need for passing cooling fluid through the porous structure without a high pressure drop.

Embodiments described herein are generally directed to porous structures with microchannels to enable the cooling fluid to have superior thermal and fluid performance in comparison to conventional porous structure heat sinks. Cooling fluid may then be ran through the microchannels with a low pressure drop to cool the porous structure and, thus, cool the heat-generating device.

Embodiments described herein also include microchannels positioned entirely within the porous structure. Microchannels positioned entirely within the porous structure provide for less resistance to a heat path through the porous structure and result in enhanced cooling of the heat-generating device.

Embodiment described herein also describe a process for generating a porous structure. The process includes depositing a photoresist material onto a target surface and then removing the photoresist material through RIE to generate the microchannels. Depositing and removing the photoresist material through RIE results in the ability to produce smaller, more accurate microchannels through the porous structure.

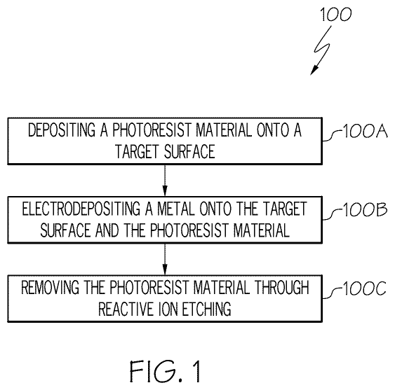

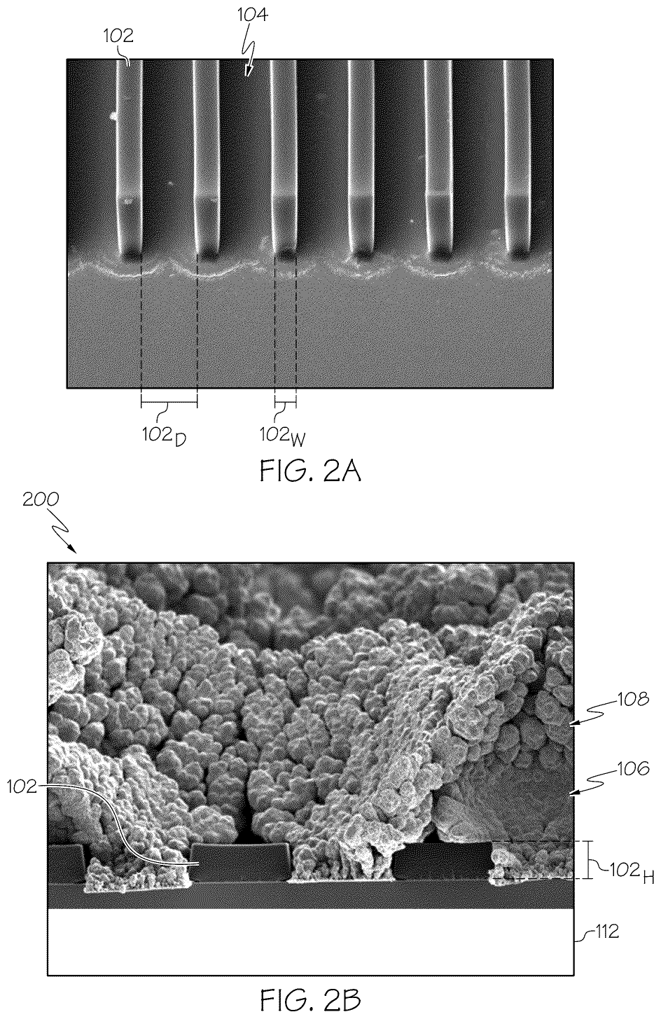

Referring now to FIG. 1 a process 100 for generating a porous structure 200 is depicted. Components of the porous structure 200 will be explained further in FIGS. 2-6 below. In block 100A, the process 100 includes depositing a photoresist material 102 onto a target surface 104. Block 100B of the process 100 includes electrodepositing a metal 106 onto the target surface 104 and the photoresist material 102. Electrodepositing the metal 106 onto the target surface 104 and the photoresist material 102 generates a metal porous structure 108. Block 100C of the process 100 includes removing the photoresist material 102 through RIE. Removing the photoresist material 102 through RIE generates at least one microchannel 110 through the metal porous structure 108.

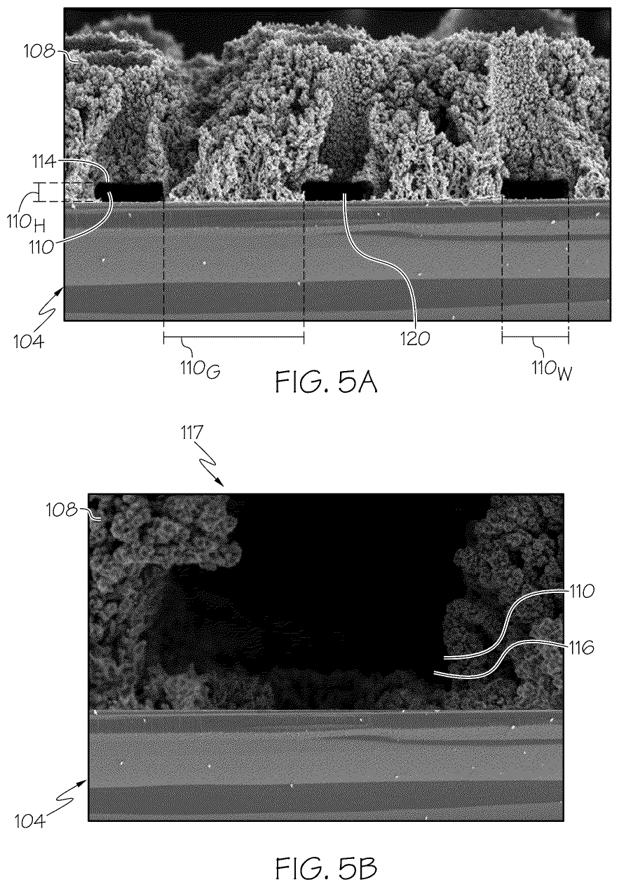

The process 100 of FIG. 1 generates the porous structure 200 of FIG. 2B. The porous structure 200 includes the target surface 104, the photoresist material 102 deposited onto the target surface 104, and the metal 106 deposited onto the target surface 104 and the photoresist material 102. An electrodeposition of the metal 106 generates the metal porous structure 108. The photoresist material 102 is removed through RIE, generating the at least one microchannel 110 (as depicted in FIG. 5A and FIG. 5B) through the metal porous structure 108.

Referring to FIG. 2A, a top-view of the photoresist material 102 is deposited onto the target surface 104 is depicted. The photoresist material 102 may be deposited onto the target surface 104 through maskless lithography. In some embodiments, a Heidelberg process may be utilized (such as with a Heidelberg MLA 150). The maskless lithography may include depositing the photoresist material 102 through spin-coating and curing the photoresist material 102. The photoresist material 102 may be cured with a laser of ultraviolet (UV) laser or any other suitable laser. The photoresist material 102 may be Bisphenol (SU8), Novolak, or any other suitable photoresist polymer. The utilization of maskless lithography allows for accurate deposition of the photoresist material 102 onto the target surface 104.

For example, the photoresist material 102 may be deposited onto the target surface 104 in parallel lines, such that a width of the line 102w is 2 microns, 5 microns, 10 microns, 20 microns, or any other suitable width. As depicted in FIG. 2B, a height of the line 102H may be 2 microns, 5 microns, 10 microns, 20 microns, or any other suitable height. Moreover, a distance between parallel lines 102D of the deposited photoresist material 102 may be less than the width of the line 102w, while still permitting growth of the metal porous structure 108 between the lines of the photoresist material 102, as depicted in FIG. 2B. In some embodiments, the photoresist material 102 is deposited onto the target surface 104 in a grid, honeycomb, or any other suitable pattern. As discussed further below, dimensions of the photoresist material 102 generally correspond to dimensions of the at least one microchannel 110 because the at least one microchannel 110 is formed when the photoresist material 102 is removed through RIE.

In some embodiments, the target surface 104 may be silicon, graphene, gallium nitride, or any other suitable material for electronics. Referring to FIG. 2B, the target surface 104 may be a surface of an electronic device 112. The electronic device 112 may be a heat-generating semiconductor device such as, but not limited to, an insulated gate bipolar transistor (IGBT), a reverse conducting IGBT (RC-IGBT), a metal-oxide-semiconductor field-effect transistor (MOSFET), a power MOSFET, a diode, a transistor, and/or combinations thereof (e.g., power cards). In some embodiments, the electronic device 112 may include a wide-bandgap semiconductor, and may be formed from any suitable material such as, but not limited to, silicon carbide (SiC), silicon dioxide (SiO₂), aluminum nitride (AlN), gallium nitride (GaN), and boron nitride (BN), and the like. In some embodiments, the electronic devices 112 operate at high current and under high temperatures, for example in excess of 250° C. and generate a large amount of heat flux that should be removed for continued operation.

The metal porous structure 108 is thermally coupled to the target surface 104 and functions to increase the surface area of the target surface 104. The increased surface area may result in increased heat flux to the surrounding environment and, thus, increased cooling capabilities, which allow the electronic device 112 to operate at higher maximum temperatures and for longer durations. The cooling fluid may also be passed through the metal porous structure 108, such as to cool the metal porous structure 108, the target surface 104, and, thus, the electronic device 112.

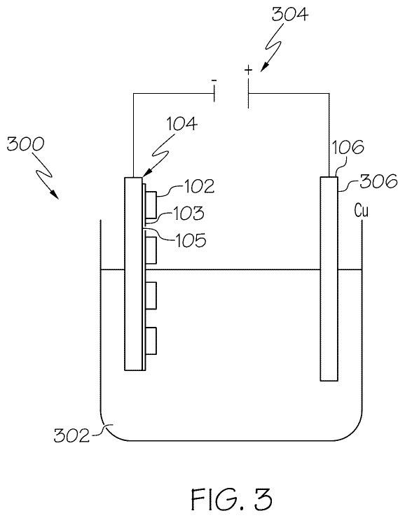

To generate the metal porous structure 108, the metal 106 may be electrodeposited through cathodic deposition onto the target surface 104 and the photoresist material 102. Referring now to FIG. 3, a process of electroplating the metal 106 to the target surface 104 having the photoresist material 102 deposited thereto is schematically illustrated. An electroplating bath 300 including a solution 302 having metal ions is prepared. The metal 106 chosen should have a relatively low coefficient of thermal expansion. In a nonlimiting example, copper may be used to electroplate the target surface 104. Therefore copper ions may be provided within the solution 302. The target surface 104 having the photoresist material 102 deposited thereto is submerged within the solution 302 of the electroplating bath 300. Additionally, an electrode 306 is submerged within the solution 302 of the electroplating bath 300. The electrode 306 may be the same material as the metal 106. A voltage source 304 is electrically coupled to both the target surface 104 and the electrode 306. In the illustrated example, the positive terminal of the voltage source 304 is electrically coupled to the electrode 306 and the negative terminal of the voltage source 304 is electrically coupled to the target surface 104. Thus, the electrode 306 is the anode and the target surface 104 is the cathode.

Electric current is provided by the voltage source 304 through the target surface 104 and the electrode 306. As a nonlimiting example, the target surface 104 may be electroplated using a DC current density of 3 A/cm2 for 50 seconds deposition time. Deposition time refers to the duration that the target surface 104 is submerged in the electroplating bath 300 with the current being applied. The solution 302 may be a copper solution of peroxysulfuric acid and copper sulfate. In some embodiments, the current may be applied for 30 seconds, 1 minute, 5 minutes, 10 minutes, 20 minutes, or any other suitable time. The current may be applied continuously or through pulsations.

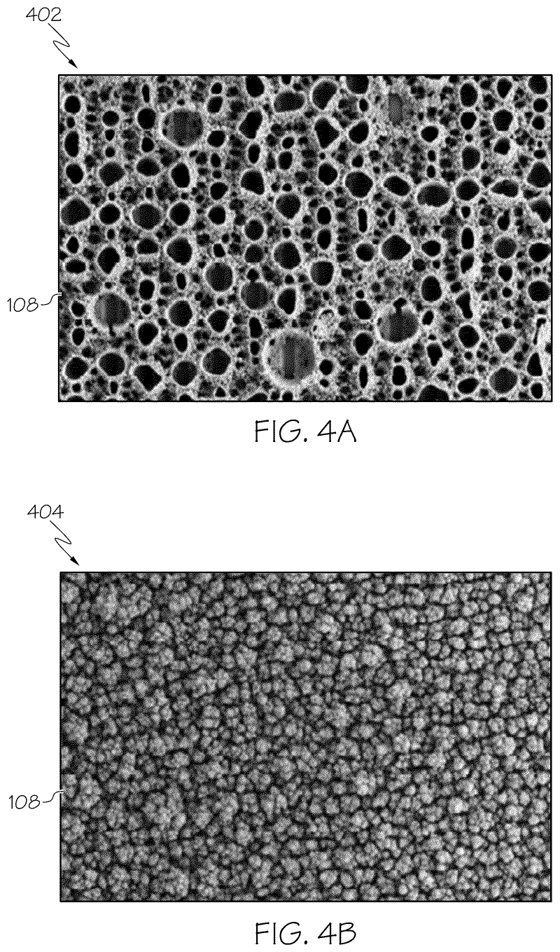

In embodiments, a higher current density results in higher pore size and, thus, higher porosity of the metal porous structure 108. Referring to FIG. 4A, a high porosity metal porous structure 402 may be generated by the electroplating. For example, the high porosity metal porous structure 402 may be generated by 0.5 A/cm2, 1 A/cm2, 2 A/cm2, 3 A/cm2, 5 A/cm2, or any other suitable current density. Conversely, referring now to FIG. 4B, a low porosity metal porous structure 404 may be generated by a low current density. For example, the low porosity metal porous structure 404 may be generated by 50 mA/cm2, 100 mA/cm2, 200 mA/cm2, or any other suitable current density for producing the low porosity metal porous structure 404. The metal porous structure 108 may have a pore diameter less than or equal to 20 microns, 40 microns, 100 microns, or any other suitable pore diameter. In embodiments, the pore size may also be adjusted by adjusting the deposition time and a concentration of the solution 302.

Depending on the current density, deposition time, and the concentration of the solution 302, the metal porous structure 108 may completely surround the photoresist material 102, resulting in a closed structure. The metal porous structure 108 may also partially surround the photoresist material 102, resulting in an open structure. Open and closed structures are discussed further below in the discussion of FIG. 5A and FIG. 5B.

Referring again to FIG. 3, in some embodiments, before the photoresist material 102 is deposited onto the target surface 104, a metal layer 103 may be deposited onto the target surface 104, producing an electrically conductive layer. The metal layer 103 may be copper, nickel, or any other electrically conductive material. The metal layer 103 protects the target surface 104 from RIE, explained further below. In embodiments, the metal layer 103 includes the same type of metal used in the metal porous structure 108. A gold layer 105 may then be deposited on the metal layer 103. The gold layer 105 protects the metal layer 103 from oxidation and increases adhesion between the target surface 104 and the photoresist material 102.

The photoresist material 102 and the gold layer 105 may be removed from the target surface 104 through RIE. RIE allows for precise control over the etching rate and profile of the photoresist material 102. The RIE removes the photoresist material 102 but does not remove the metal porous structure 108, generating the at least one microchannel 110 through metal porous structure 108. The RIE may utilize CF4/O2 plasma, or any other suitable plasma or ions, in a vacuum chamber. In embodiments, other methods that remove polymer material may also be used to remove the photoresist material 102 from the target surface 104, while leaving the metal porous structure 108.

Referring now to FIG. 5A and FIG. 5B, the at least one microchannel 110 may be generated through the metal porous structure 108 when the photoresist material 102 is removed through RIE. As discussed hereinabove, a high pressure drop may be present when the cooling fluid flows through the metal porous structure 108. This is especially true in the low porosity metal porous structure 404, in which there is less volume for the cooling fluid to flow through the metal porous structure 108. The at least one microchannel 110 permits the cooling fluid to pass through the metal porous structure 108 without a high pressure drop. The microchannel 110 may be square, rectangular, or circular in cross-section. There may be a single microchannel 110, or a plurality of microchannels 110. The plurality of microchannels 110 may be substantially parallel, substantially perpendicular, or in any other suitable arrangement.

The at least one microchannel 110 may have a microchannel height 110H substantially perpendicular to the target surface 104 of 5 microns, 10 microns, 20 microns, or any other suitable height for flowing the cooling fluid through the microchannel 110. The at least one microchannel 110 may have a microchannel width 110w substantially parallel to the target surface 104 of 2 microns, 5 microns, 10 microns, 20 microns, or any other suitable width for flowing the cooling fluid through the microchannel 110. Dimensions of the microchannel 110 generally correspond to the photoresist material dimensions (102H and 102w). The distance between parallel lines 102D of the photoresist material 102 also generally corresponds to a gap 110G substantially parallel to the target surface 104 between the plurality of microchannels 110. In some embodiments, the microchannel width 110w is greater than the gap 110G between the plurality of microchannels 110. In such embodiments, the metal porous structure 108 may still be electrodeposited in the gap 110G between the plurality of microchannels 110.

As depicted in FIG. 5A, removal of the photoresist material 102 through the RIE may generate the at least one microchannel 110, such that a closed microchannel 114 is formed. In alternative embodiments, as depicted in FIG. 5B, removal of the photoresist material 102 through the RIE may generate the at least one microchannel 110, such that an open microchannel 116 is formed. When the at least one microchannel 110 is closed, the closed microchannel 114 is positioned on the target surface 104 and the metal porous structure 108 surrounds the closed microchannel 114. When the at least one microchannel 110 is open, the open microchannel 116 is positioned on the target surface 104 and the metal porous structure 108 only partially surrounds the open microchannel 116, such that a top end 117 of the open microchannel 116 is exposed to the environment. The closed microchannel 114 results from longer deposition times when compared to deposition times for the open microchannel 116. For example, the target surface 104 may be submerged in the electroplating bath 300 for 30 seconds to generate the open microchannel 116, while the target surface 104 may be submerged in the electroplating bath 300 for 4 minutes to generate the closed microchannel 114. In some embodiments, a first portion of the at least one microchannel 110 may be closed and a second portion of the at least one microchannel 110 may be open.

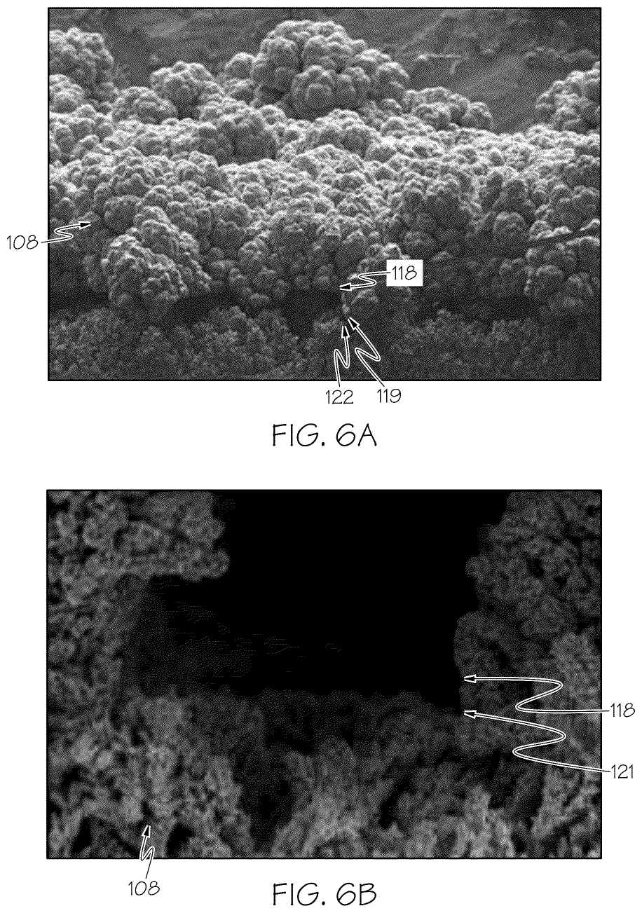

Referring now to FIG. 6A and FIG. 6B, the at least one microchannel 110 may also be positioned entirely within the metal porous structure 110, generating an enclosed microchannel 118, such that the enclosed microchannel 118 is not in fluid contact with the target surface 104. The enclosed microchannel 118 may be generated by depositing the photoresist material 102 onto the metal porous structure 108, rather than on the target surface 104, and then further electrodepositing the metal 106 onto the photoresist material 102 and the metal porous structure 108. For example, the metal porous structure 108 may be electrodeposited onto the target surface 104, as explained hereinabove. The photoresist material 102 may then be deposited onto the metal porous structure 108. The metal porous structure 108 may then be further electrodeposited over the photoresist material 102. The photoresist material 102 may then be removed through the RIE, generating the enclosed microchannel 118. In some embodiments, the metal layer 103 and the gold layer 105 may be deposited onto the photoresist material 102 and the metal porous structure 108, and then the metal 106 may be electrodeposited onto the gold layer 105 to generate the metal porous structure 108.

The enclosed microchannel 118 may be open or closed. As discussed hereinabove, whether the enclosed microchannel 118 is open or closed depends on the time the target surface 104 is submerged in the electroplating bath 300. As discussed hereinabove, a longer deposition time will result in a closed enclosed microchannel 119, as depicted in FIG. 6A, while a shorter deposition time will result in an open enclosed microchannel 121, as depicted in FIG. 6B.

In some embodiments, the porous structure 200 may include microchannels 110 that are layered. For example, a first microchannel 120 may be positioned on the target surface 104 (as depicted in FIG. 5A) and a second microchannel 122 may be positioned entirely within the metal porous structure 108 (as depicted in FIG. 6A). In such an embodiment, the first microchannel 120 is a closed microchannel 114 and the second microchannel 122 is an enclosed microchannel 118.

It should now be understood that embodiments of the present disclosure are directed to structures and methods that provide enhanced cooling of a heat-generating device. Cooling fluid passing through metal porous structures may receive heat of the heat-generating device, specifically, power electronic devices with increased power density. The cooling fluid may be passed through at least one microchannel through the metal porous structure, dissipating heat produced by the power electronic device. This effectively lowers the operating temperature of the power electronics and allows for continuous operation of the power electronics, even when the power electronics are subject to increased power demands, and increased operational life of the power electronic components.

It is noted that recitations herein of a component of the present invention being “configured” in a particular way, “configured” to embody a particular property, or function in a particular manner, are structural recitations as opposed to recitations of intended use. More specifically, the references herein to the manner in which a component is “configured” denotes an existing physical condition of the component and, as such, is to be taken as a definite recitation of the structural characteristics of the component.

It is noted that one or more of the following claims utilize the term “wherein” as a transitional phrase. For the purposes of defining the present invention, it is noted that this term is introduced in the claims as an open-ended transitional phrase that is used to introduce a recitation of a series of characteristics of the structure and should be interpreted in like manner as the more commonly used open-ended preamble term “comprising”.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

1. A porous structure comprising:
a target surface;
a photoresist material deposited onto the target surface; and
a metal electrodeposited onto the target surface and the photoresist material, wherein:
an electrodeposition of metal generates a metal porous structure, and
the photoresist material is removed through reactive ion etching, generating at least one microchannel through the metal porous structure.

2. The porous structure of claim 1, further comprising:
a metal layer deposited onto the target surface; and
a gold layer deposited onto the metal layer, wherein the gold layer is removed through the reactive ion etching.

3. The porous structure of claim 1, wherein the at least one microchannel is closed.

4. The porous structure of claim 1, wherein the at least one microchannel is open.

5. The porous structure of claim 1, wherein the at least one microchannel is positioned entirely within the metal porous structure.

6. The porous structure of claim 1, further comprising:
a first microchannel positioned on the target surface; and
a second microchannel positioned entirely within the metal porous structure.

7. The porous structure of claim 1, further comprising a plurality of microchannels, wherein a microchannel width substantially parallel to the target surface is greater than a gap substantially parallel to the target surface between the plurality of microchannels.

8. The porous structure of claim 1 further comprising a plurality of microchannels, wherein the plurality of microchannels are substantially parallel.

9. The porous structure of claim 1, wherein the metal porous structure has pores less than or equal to 100 micrometers in diameter.

10. The porous structure of claim 1, wherein a microchannel width substantially parallel to the target surface is less than or equal to 20 micrometers.

11. The porous structure of claim 1, wherein a microchannel height substantially perpendicular to the target surface is less than or equal to 20 micrometers.

12. The porous structure of claim 1, wherein the metal is copper or nickel.

13. The porous structure of claim 1, wherein the target surface is silicon.

14. The porous structure of claim 1, wherein the photoresist material is SU8.

15. A process for generating a porous structure comprising:
depositing a photoresist material onto a target surface;
electrodepositing a metal onto the target surface and the photoresist material, wherein the electrodepositing generates a metal porous structure; and
removing the photoresist material through reactive ion etching, wherein removing the photoresist material through the reactive ion etching generates at least one microchannel through the metal porous structure.

16. The process of claim 15, further comprising:
depositing a metal layer above the photoresist material and the metal porous structure;
depositing a gold layer above the metal layer; and
electrodepositing the metal onto the gold layer, wherein the electrodepositing generates the metal porous structure, wherein:
removing the photoresist material through the reactive ion etching generates the at least one microchannel positioned entirely within the metal porous structure.

17. The process of claim 15, further comprising curing the photoresist material with ultraviolet light.

18. The process of claim 15, wherein the at least one microchannel is open.

19. The process of claim 15, further comprising:
depositing a metal layer onto the target surface; and
depositing a gold layer onto the metal layer, wherein the gold layer is removed through the reactive ion etching.

20. The process of claim 15, wherein:
a first microchannel is positioned on the target surface; and
a second microchannel is positioned entirely within the metal porous structure.
